(19) United States
(12) Patent Application Publication
(10) Pub. No.: US 2003/0132868 A1
(43) Pub. Date: Jul. 17, 2003

(54) Frequency converter for converting a digital baseband signal into a real bandpass signal

(76) Inventors: Axel Clausen, Munchen (DE); Moritz Harteneck, Munchen (DE); Matthias Kindler, Neubiberg (DE)

Correspondence Address: JENKINS & WILSON, PA, 3100 TOWER BLVD, SUITE 1400, DURHAM, NC, 27707, US

(21) Appl. No.: 10/341,767

(22) Filed: Jan. 14, 2003

(30) Foreign Application Priority Data
Jan. 15, 2002 (DE) 10201284.9

(51) Int. Cl. H03M 1/66

(52) U.S. Cl. 341/144

(57) ABSTRACT

The invention relates to a frequency converter for converting a digital baseband signal (2) having a first frequency (0 Hz) into an analog output signal (8), which is centered around a second frequency (f_{z}, f₁+f_{z}, f₂+f_{z}), which is switched in rapidly successive frequency jumps, and to a corresponding method. In order to improve the performance of the frequency converter with regard to the rapid switching of the transmission frequency (f_{z}, f₁+f_{z}, f₂+f_{z}), it is proposed to provide the frequency converter with a digital mixer (9), which transforms the digital baseband signal (2) fed to it to a low intermediate frequency (f₁, f₂), a D/A converter (3) for converting the baseband signal (4) supplied by the digital mixer (9) into an analog bandpass signal (6), and an analog mixer (7), which transforms the analog bandpass signal (6) with a predetermined constant factor (f_{z}) into a real bandpass signal (8) which is centered around the transmission frequency (f_{z}, f₁+f_{z}, f₂+f_{z}).

### TECHNICAL FIELD

The invention relates to a frequency converter for converting a digital, in particular complex-value, baseband signal into a real bandpass signal in accordance with the preamble of Patent claim 1, and to a corresponding method in accordance with the preamble of Patent claim 9.

### BACKGROUND ART

Frequency converters for converting a digital, complex baseband signal into an analog, real bandpass signal are used e.g. in two-way data transmission systems in order to transmit data from an end customer (subscriber station) to a so-called head-end.

A typical example of such a frequency converter in accordance with the prior art is illustrated in FIG. 1. The frequency converter shown in FIG. 1 essentially comprises a D/A converter 3, a first analog mixer 5 and a second analog mixer 7. The frequency converter has both digital and analog components, the boundary between digital and analog domains being represented by a dashed line.

The data to be transmitted (input data) are firstly conditioned in a modulator 1 with an interpolation and pulse shaping unit and are fed to the frequency converter as a digital, complex baseband signal 2. This baseband signal 2 is usually centered around 0 Hz.

The D/A converter 3, which simultaneously forms the input of the frequency converter, firstly converts the digital, complex baseband signal 2 into an analog, complex baseband signal 4, which the first mixer 5 transforms into a real bandpass signal 6 which is centered around an intermediate frequency f0, f1 or f2 (also cf. FIG. 4). Finally, the second mixer 7 converts the real bandpass signal 6 with a fixed factor f_{z} into a real bandpass signal 8 having a transmission frequency f₀+f_{z}, f₁+f_{z} or f₂+f_{z}.

The international Patent Application WO 00/60732 discloses a frequency converter for converting a digital baseband signal having a first frequency into an analog bandpass signal having a second frequency. The frequency converter illustrated in FIG. 1 comprises a digital mixer, which transforms the digital baseband signal to an intermediate frequency, and also a D/A converter for converting the signal output by the digital mixer into an analog signal, and an analog mixer for transforming the signal converted by the D/A converter into the bandpass signal having the second frequency. However, the known frequency converter is not suitable for data transmission by the MF-TDMA method since the baseband signal is not transformed to a variable intermediate frequency but rather to a fixed intermediate frequency.

The textbook KAMMEYER, K. D.: Nachrichtenübertragung [Telecommunications] 1992, Stuttgart, Teubner Verlag, ISBN 3-519-06142-2, pages 272-274, discloses the theoretical principles of types of modulation for transforming a bandpass signal having a first frequency into a bandpass signal having a second frequency. By contrast, an indication of a frequency converter in accordance with Patent claim 1 or a method in accordance with Patent claim 9 for data transmission by the MF-TDMA method cannot be gathered from this document.

US 2001/0033200 discloses a frequency converter which transforms a low-frequency input signal into a high-frequency output clock. The frequency converter illustrated in FIGS. 4 and 5 comprises a TDFS circuit and also a PLL (loop control synchronization circuit). The PLL serves for setting the frequency of an oscillator in such a way that it corresponds to the frequency of the TDFS circuit or is a multiple thereof, to be precise so accurately that the phase shift does not drift. The PLL thus has very good frequency multiplication properties. The following holds true in this case: f_{RF}=N·f_{TDFS}. A frequency transformation with a predetermined constant frequency does not take place in this case.

As mentioned, the digital, complex baseband signal 2 is usually centered around 0 Hz. By contrast, the center frequency of the real, analog output signal 8 is about 2-3 GHz. For the transmission of data by the MF-TDMA method (multi-frequency time division multiple access), the transmission frequency of the output signal 8 has to be varied in relatively rapid frequency jumps, the frequency jumps amounting, for example, to ±10 MHz (in this respect, see DVB-RCS specification EN301.790).

The frequency transformation of this frequency converter having two analog mixers 5, 7 is illustrated in FIG. 4. In this case, the abovementioned small frequency jumps are generated by the first analog mixer 5, which steps up the baseband signal to a variable intermediate frequency f0, f1 or f2.

The digital, complex baseband signal 2 centered around 0 Hz is represented in the center of FIG. 4, at 0 Hz. Said baseband signal 2 is transformed by the first analog mixer 5 into a real bandpass signal 6 which is centered around a variable intermediate frequency f0, f1 or f2. Since real-value signals are involved, they each also have a negative frequency component at −f0, f1 or −f2.

Finally, the real bandpass signal 6 is set to the transmission frequency f₀+f_{z}, f₁+f_{z} or f₂+f_{z} by the second analog mixer 7 with a fixed factor f_{z}. The transmission signals, as real-value signals, also each have a negative frequency component −(f₀+f_{z}), −(f₁+f_{z}) or −(f₂+f_{z}).

The frequency jumps can be generated either, as described, by means of the first mixer 5, the second mixer 7 then transforming the variable bandpass signal 6 only with a constant factor f_{z} to the transmission frequency f₀+f_{z}, f₁+f_{z} or f₂+f_{z} by means of the second mixer 7, which transforms the bandpass signal 6 from a fixed intermediate frequency to a variable transmission frequency f₀+f_{z}, f₁+f_{z} or f₂+f_{z}.

The capability of the analog mixers 5, 7 to switch the output signal 8 in rapid frequency jumps is limited on account of the transient recovery time required for this. Moreover, the communication between the controller and one of the analog mixers 5, 7, which is necessary for changing over the output frequency, is relatively complicated.

### SUMMARY OF THE INVENTION

Therefore, the object of the present invention is to provide a frequency converter which enables a rapid switching of the transmission frequency in a simple manner.

This object is achieved according to the invention by means of the features specified in Patent claims 1 and 9, respectively. Subclaims relate to further refinements of the invention.

The essential concept of the invention consists in providing a digital mixer which transforms the digital base b and signal, which is centered around a first frequency (0 Hz), to an intermediate frequency, converting the bandpass signal centered around the intermediate frequency into an analog signal by means of a D/A converter and providing an analog mixer, which transforms the analog signal with a predetermined constant factor into an analog, real bandpass signal which is centered around a transmission frequency, the frequency jumps required for the transmission by the MF-TDMA method being generated by the digital mixer.

Carrying out the small frequency jumps in the digital domain has the advantage that transient recovery times as in the analog mixers, do not have to be taken into account and the communication between a controller and the digital mixer is not time-critical.

The baseband signal can be transformed by the digital mixer either into a real or complex-value bandpass signal which is centered around the intermediate frequency.

The intermediate frequency preferably lies near the frequency of the baseband signal. The frequency jumps generated by the digital mixer are relatively small and preferably amount to less than 100 MHz, in particular ±10 or ±20 MHz.

The bandpass signal which is output by the D/A converter and which may be either real or complex-value is transformed by the analog mixer preferably with a fixed conversion factor into the real bandpass signal.

The frequency converter is preferably part of a network interface in a two-way data transmission system, in particular a two-way satellite transmission system.

### BRIEF DESCRIPTION OF THE DRAWINGS

The invention is explained in more detail below by way of example with reference to the accompanying drawings, in which:

FIG. 1 shows a frequency converter having two analog mixers according to the prior art;

FIG. 2 shows a first exemplary embodiment of a frequency converter;

FIG. 3 shows a second exemplary embodiment of a frequency converter.

FIG. 4 shows a representation of the frequency conversion in the frequency converter from FIG. 1; and

FIG. 5 shows a representation of the frequency conversion in a frequency converter in accordance with an exemplary embodiment of the invention.

### DETAILED DESCRIPTION OF THE INVENTION

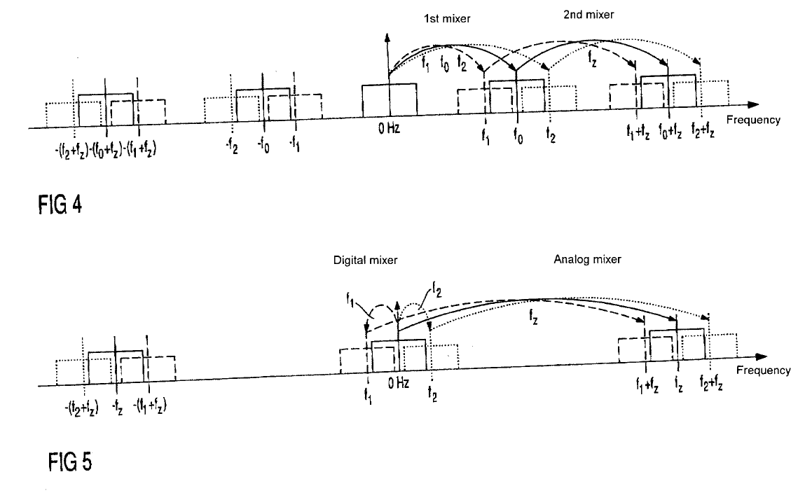

With regard to the explanation of FIGS. 1 and 4, reference is made to the introduction to the description.

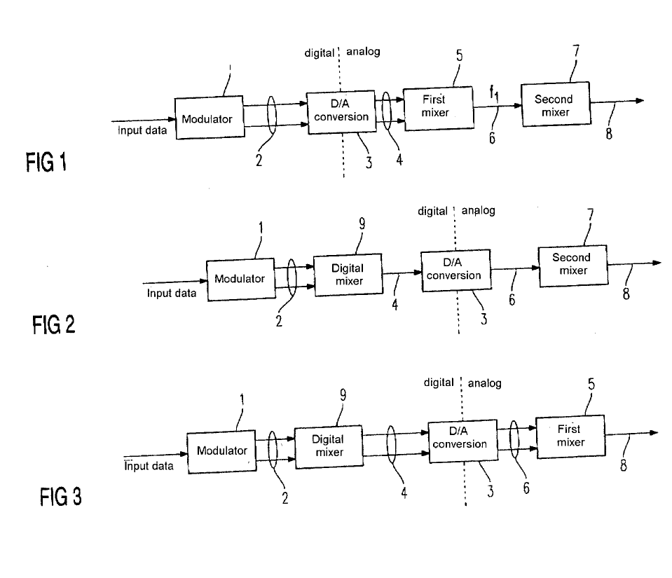

FIGS. 2 and 3 show a frequency converter for converting a digital, complex-value baseband signal 2, which is centered around 0 Hz, into a real, analog bandpass signal 8, which is centered around a variable transmission frequency f_{z}, f₁+f_{z} or f₂+f_{z}, which is switched in rapidly successive, small frequency jumps. In both embodiments, the frequency converter comprises a digital mixer 9, a D/A converter 3 and an analog mixer 7.

The difference between the embodiment of FIG. 2 and that of FIG. 3 is that the digital mixer 9 transforms the baseband signal 2 into a real-value bandpass signal 4 in FIG. 2, and into a complex-value bandpass signal 4 in FIG. 3.

In FIG. 2, the digital mixer 9 transforms the complex baseband signal 2 received from a modulator 1 into a digital, real bandpass signal 4 which is centered around a low intermediate frequency f1 or f2 or 0 Hz. The intermediate frequency f1, f2 is predeterminable. The intermediate frequency is low and is preferably about ±10 MHz.

A bandpass signal 4 output by the digital mixer 9 is then converted into an analog, real bandpass signal 6 by means of the D/A converter 3 and is fed to an analog mixer 7. The analog mixer 7 transforms the bandpass signal 6 obtained into a real bandpass signal 8 which is centered around a transmission frequency f_{z}, f₁+f_{z} or f₂+f_{z} (cf. FIG. 5).

In this embodiment, the complexity of the frequency converter is reduced since only one D/A converter 3 (for a real signal) is required. Moreover, the requirements made of the analog mixer 7 with regard to the transient recovery time become less stringent since said mixer steps up continuously by a fixed frequency f_{z} and small frequency jumps are realized by the digital mixer 9 in the digital domain.

The embodiment illustrated in FIG. 3 comprises a digital mixer 9, which transforms the digital, complex-value baseband signal 2 into a complex bandpass signal 4 which is centered around an intermediate frequency f1 or f2 or 0 Hz. This complex bandpass signal 4 is again converted into a complex bandpass signal 6 in analog form by the D/A converter 3 (also cf. FIG. 5).

The conversion from the complex-value signal into a real signal is only effected by the analog mixer 5 which transforms the complex bandpass signal 6 with a fixed factor f_{z} into the real transmission signal 8.

Here, too, the requirements with regard to the transient recovery time of the analog mixer 5 are less stringent since the frequency jumps are carried out in the digital domain and the analog mixer 5 steps up only by a fixed factor f_{z}.

FIG. 5 shows the transformation—carried out by the frequency converter according to FIG. 3—of the digital baseband signal 2 into the bandpass signal 4 with an intermediate frequency f1 or f2 lying near to 0 Hz, and the transformation of the complex-value bandpass signal 4 to the transmission frequency f_{z}, f₁+f_{z} or f₂+f_{z}.

Such a configuration enables a simple and rapid switching of the transmission frequency fₛ.

What is claimed is:

1. Frequency converter for converting a digital baseband signal having a first frequency into an analog bandpass signal having a second frequency, which is set up for the transmission of data by the MF-TDMA method whereby:
(a) a digital mixer, which is driven by a controller and transforms the baseband signal to a variable intermediate frequency in order to generate frequency jumps which are necessary for data transmission by the MF-TDMA method,
(b) a D/A converter for converting the signal output by the digital mixer into an analog signal, and
(c) an analog mixer for transforming the signal converted by the D/A converter with a predetermined, constant frequency into the bandpass signal having the second frequency.

2. Frequency converter according to claim 1, wherein the digital mixer receives a complex baseband signal and converts it into a real bandpass signal which is fed to the D/A converter.

3. Frequency converter according to claim 1, wherein the digital mixer receives a complex baseband signal and converts it into a complex bandpass signal which is fed to the D/A converter.

4. Frequency converter according to claim 1, wherein the analog mixer receives a real signal and converts it into the real bandpass signal.

5. Frequency converter according to claim 1, wherein the analog mixer receives a complex signal and converts it into the real bandpass signal.

6. Frequency converter according to claim 1, wherein the frequency converter transforms a digital, complex baseband signal into an analog, real bandpass signal.

7. Frequency converter according claim 1, wherein the digital baseband signal is a signal centered around 0 Hz.

8. Network interface, in particular for a two-way satellite transmission system, having a frequency converter according to claim 1.

9. Method for converting a digital baseband signal having a first frequency to an analog output signal having a second frequency, frequency jumps being generated for the transmission of data by the MF-TDMA method, wherein:
(a) transformation of the digital baseband signal by means of a digital mixer, driven by a controller, to a variable intermediate frequency, the frequency jumps required for data transmission by the MF-TDMA method being generated by the digital mixer,
(b) D/A conversion of the transformed signal into an analog signal, and
(c) transformation of the analog signal with a predetermined, fixed frequency into the analog output signal having the second frequency.

10. Method according to claim 9, wherein the baseband signal is a complex-value digital signal which is transformed into a real, analog output signal.

11. Method according to claim 9, wherein the digital mixer transforms the baseband signal to a variable intermediate frequency which lies near to the first frequency.

12. Method according to claim 11, wherein the intermediate frequency deviates at most ±50 MHz, ±20 MHz or ±10 MHz from the frequency of the baseband signal.
